(19) United States
(12) Patent Application Publication
(10) Pub. No.: US 2015/0043152 A1
(43) Pub. Date: Feb. 12, 2015

(54) MOUNTING APPARATUS FOR HARD DISK DRIVE AND ELECTRONIC DEVICE WITH THE MOUNTING APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: GUANG-YI ZHANG, Shenzhen (CN); GUI-DONG SONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/974,022

(22) Filed: Aug. 22, 2013

(30) Foreign Application Priority Data
Aug. 9, 2013 (CN) 2013103452754

(51) Int. Cl. G06F 1/18; H05K 5/02

(52) U.S. Cl. CPC G06F 1/187; H05K 5/0217
USPC 361/679.37; 248/298.1; 312/333

(57) ABSTRACT

A mounting apparatus for a hard disk drive (HDD) which does not require screw fixings includes a bracket and a carrier received in the bracket. The HDD includes sidewalls and a pin extending out from a sidewall. The carrier includes a shell, a resilient unlocking member installed on a side of the shell, and an operation member. The HDD is received in the shell. The operation member includes a connecting portion with rotating latching member mounted to a front end of the shell. The unlocking member defines a position hole for the pin of the HDD. A front end of the bracket defines a first locating hole. A block portion of the latching member latches in the first locating hole, and a second end of the latching member is detachably latched to the connecting portion.

### BACKGROUND

1. Technical Field

The present disclosure relates to electronic devices, and more particularly, to an electronic device with a mounting apparatus for mounting a hard disk drive (HDD).

2. Description of Related Art

In computers, a HDD stores information. The HDD is usually mounted in a bracket of the computer. The HDD is directly inserted into the bracket, and a large number of screws extend through sidewalls of the bracket to fix the HDD to the bracket. However, mounting or removing the HDD to or from the bracket requires a tool to fasten or release the screws. Thus, the assembly and disassembly of the HDD are not only time-consuming but also laborious.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded view of an exemplary embodiment of an electronic device, wherein the electronic device includes a carrier, two rails, and an unlocking member.

FIG. 2 is an enlarged view of the carrier of FIG. 1.

FIG. 3 is an enlarged view of one of the rails of FIG. 1.

FIG. 4 is an enlarged view of the unlocking member of FIG. 1.

FIG. 5 is a partially assembled view of the electronic device of FIG. 1.

FIG. 6 is an assembled view of the electronic device of FIG. 1.

FIGS. 7-9 are views showing the processes of assembling a hard disk drive.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

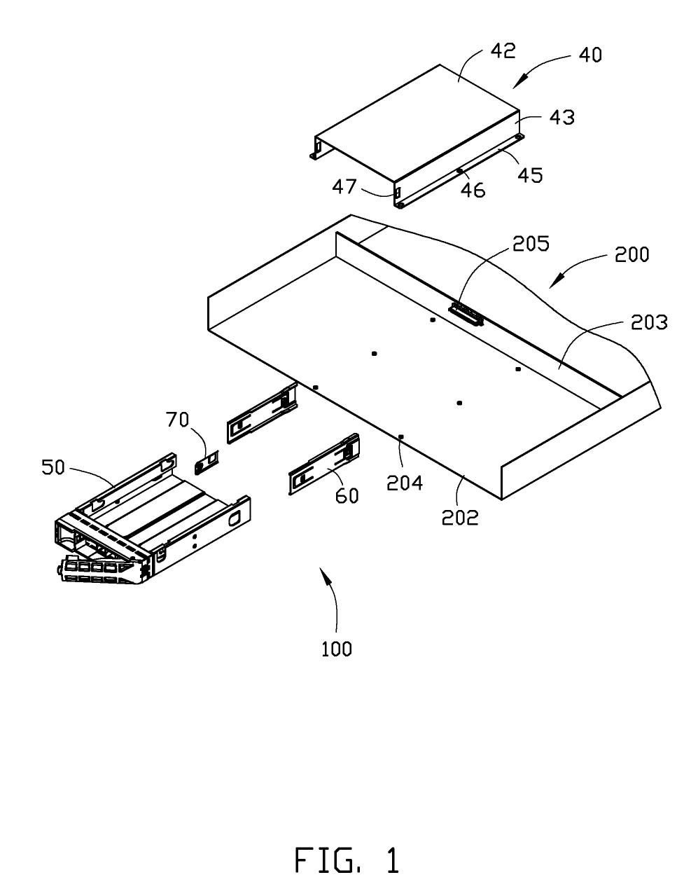

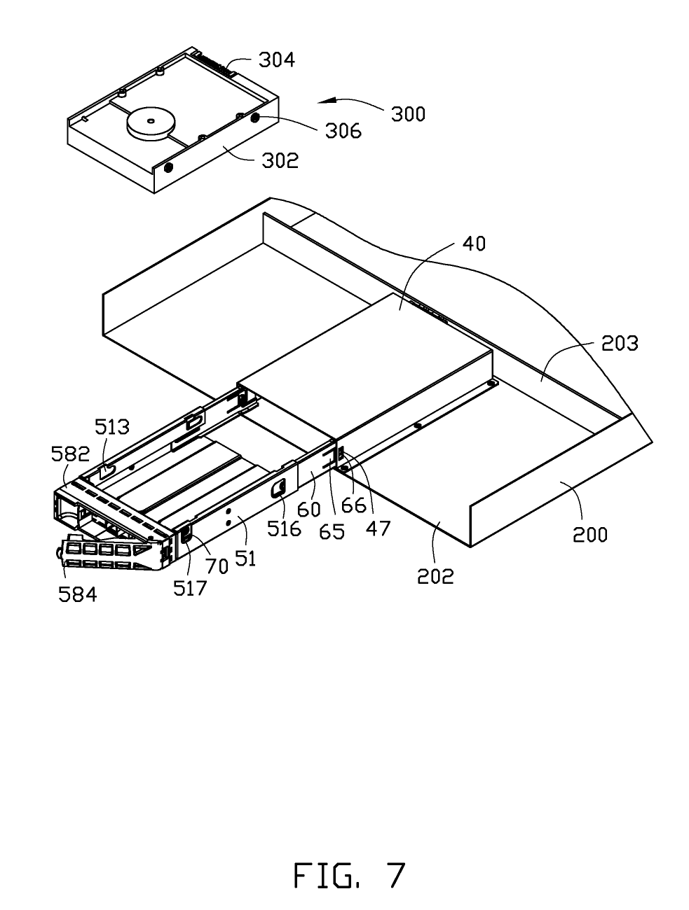

FIGS. 1 and 7 show an exemplary embodiment of an electronic device including a chassis 200, a hard disk drive (HDD) 300, and a mounting apparatus 100 for mounting the HDD 300 in the chassis 200. The mounting apparatus 100 includes a bracket 40, a carrier 50, two rails 60, and an unlocking member 70.

The chassis 200 includes a bottom wall 202 and a circuit board 203 perpendicularly mounted on a middle of the bottom wall 202. The bottom wall 202 defines a plurality of screw holes 204 in front of the circuit board 203. A first connector 205 is mounted on a front side of the circuit board 203 facing the screw holes 204.

The HDD 300 includes two opposite sidewalls 302 and a second connector 304 mounted to a rear end of the HDD 300. Two spaced pins 306 are mounted on two opposite ends of each sidewall 302. In the embodiment, each pin 306 is a screw.

The bracket 40 includes a rectangular top plate 42, two opposite side plates 43 perpendicularly extending down from opposite sides of the top plate 42, and two flanges 45 protruding out from bottom sides of the side plates 43. Each flange 45 defines a plurality of through holes 46. Front ends of the side plates 43 define two opposite first locating holes 47.

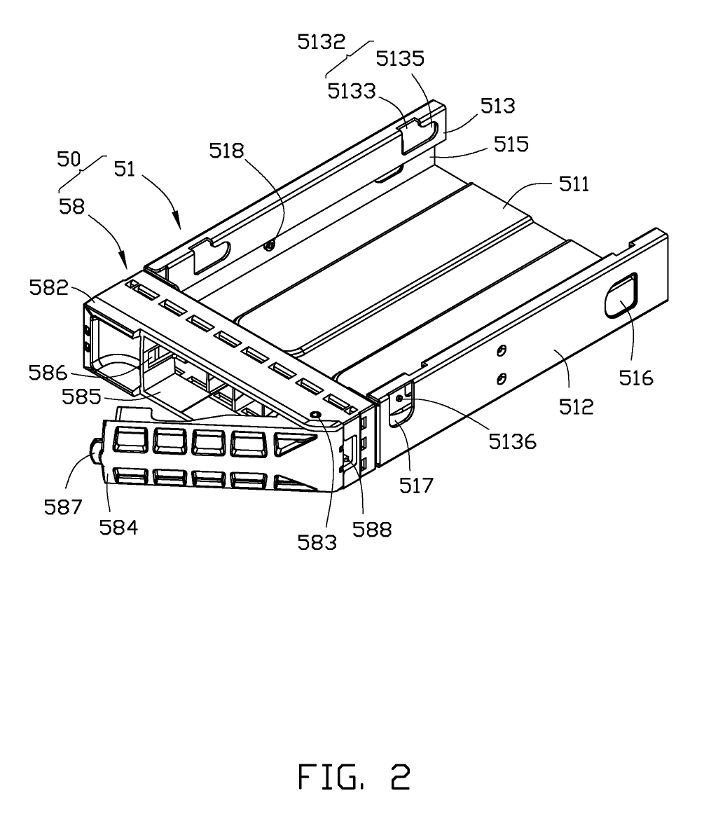

FIG. 2 shows the carrier 50 including a shell 51 and an operation assembly 58. The shell 51 includes a substantially rectangular base plate 511, two opposite supporting plates 512 perpendicularly extending up from opposite sides of the base plate 511, and two substantially L-shaped position plates 513 extending in and then extending down from top sides of the supporting plates 512. The supporting plates 512 and the position plates 513 cooperatively bound two parallel slide slots 515. Rear ends of the supporting plates 512 define two opposite second locating holes 516, and a front end of one of the supporting plates 512 defines an operation hole 517. Two poles 518 protrude toward the slide slot 515 from middle portions of the supporting plates 512. Front and rear ends of each position plate 513 define two installing holes 5132. Each installing hole 5132 is substantially L-shaped, and includes an access portion 5133 extending down from a top of the position plate 513, and a receiving portion 5135 extending rearward from a bottom end of the access portion 5133. The operation hole 517 is located adjacent to the installing hole 5132. A latching pole 5136 protrudes from the position plate 513 toward the operation hole 517.

The operation assembly 58 includes a connecting rack 582 mounted on the front end of the shell 51 and a latching member 584. A front side of the connecting rack 582 defines a receiving space 585 for receiving the latching member 584. A first end of the latching member 584 is rotatably connected to a first end of the connecting rack 582 through a shaft 583, and a resilient hook 587 protrudes from a second end of the latching member 584 opposite to the shaft 583. A block 588 protrudes from the first end of the latching member 584 opposite to the hook 587. A second end of the connecting rack 582 opposite to the shaft 583 defines a latching hole 586 communicating with the receiving space 585. The hook 587 can be detachably latched in the latching hole 586 of the connecting rack 582. If the hook 587 is latched in the latching hole 586, the block 588 is exposed out from the first end of the connecting rack 582.

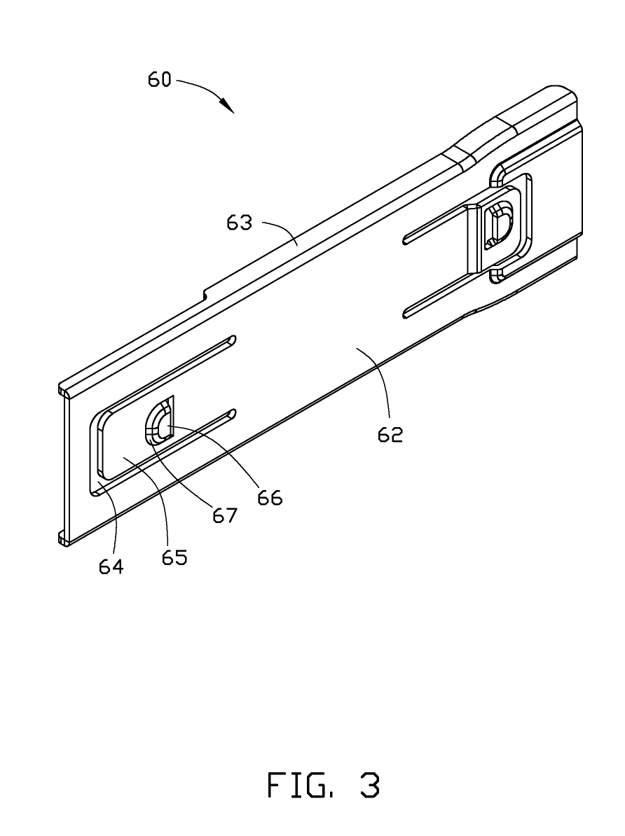

FIG. 3 shows each rail 60 including a substantially rectangular sliding plate 62 and two opposite flanges 63 protruding from top and bottom sides of the sliding plate 62. Two opposite ends of the sliding plate 62 define receiving slots 64 extending along the lengthwise direction of the sliding plate 62. A resilient tongue 65 extends into each receiving slot 64 from an end wall bounding the receiving slot 64 adjacent to a middle portion of sliding plate 62. A wedge-shaped abutting block 66 extends out from a distal end of each tongue 64. Each abutting block 66 defines a slanting guiding surface 67 opposite to the middle portion of the sliding plate 62.

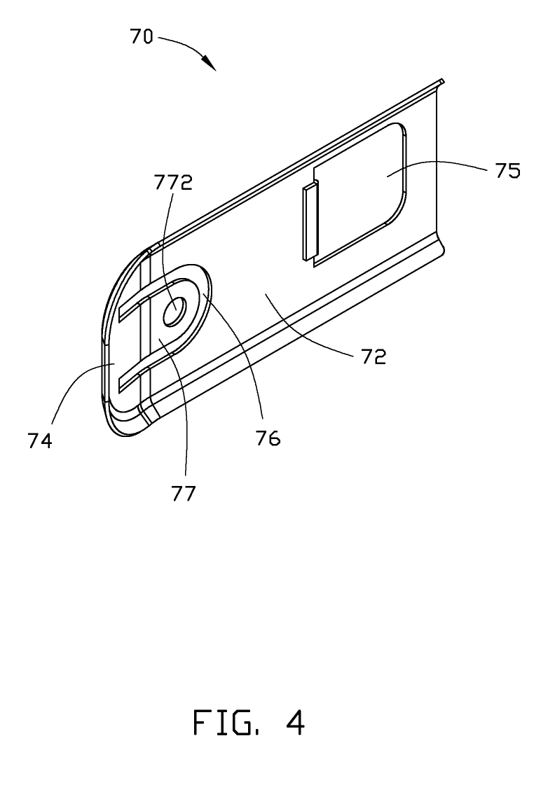

FIG. 4 shows that the unlocking member 70 made of resilient material, including a substantially rectangular abutting plate 72 and an operation plate 74 slantingly extending out from a front end of the abutting plate 72. A rear end of the abutting plate 72 defines a position hole 75 opposite to the operation plate 74. A junction of the operation plate 74 and the abutting plate 72 defines a rectangular through hole 76. A resilient tongue 77 extends into the through hole 76 from an end wall bounding the through hole 76 adjacent to the operation plate 74. A distal end of the tongue 77 defines a mounting hole 772.

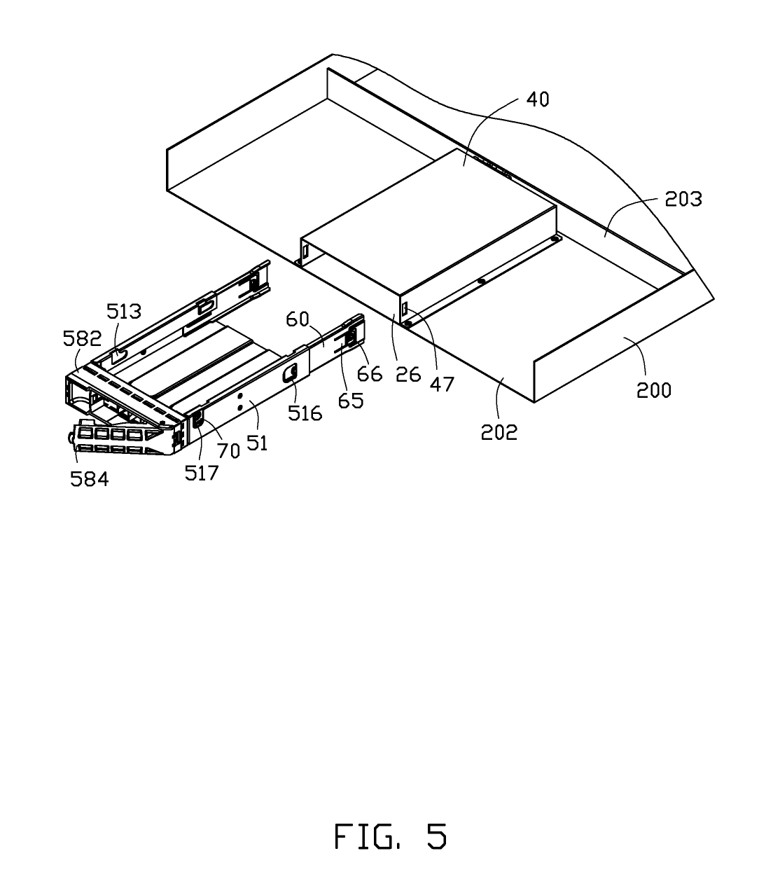

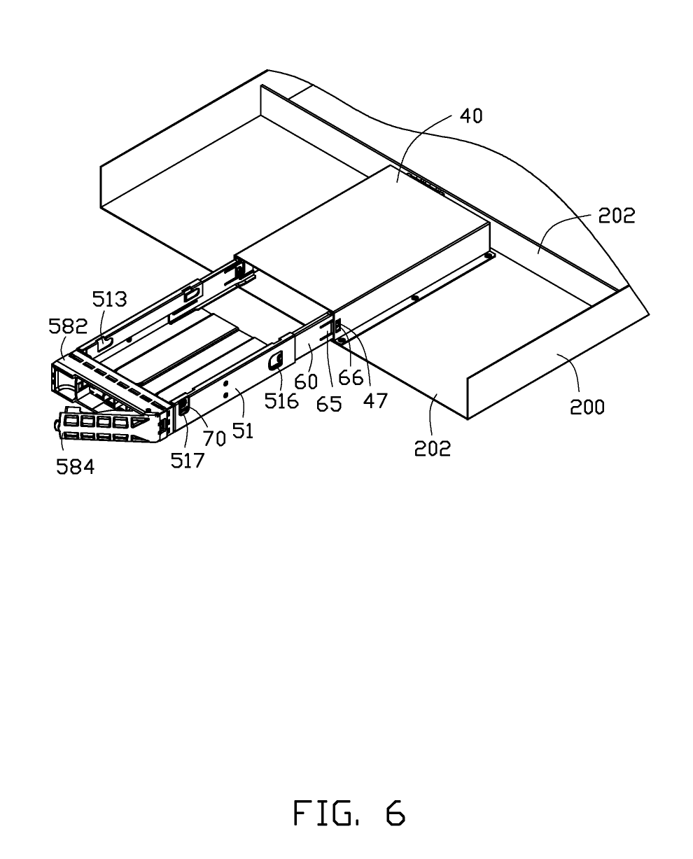

FIGS. 5-6 show that, in assembly, the bracket 40 is supported on the bottom wall 202 of the chassis 200. The through holes 46 of the bracket 40 align with the screw holes 204 of the bottom wall 202. A plurality of screws extends through the through holes 46, to be screwed in the screw holes 204. The bracket 40 and the chassis 200 cooperatively bound an installing space 26. The unlocking member 70 is sandwiched between the supporting plate 512 with the operation hole 517 and the position plate 513, to allow the operation plate 74 of the unlocking member 70 to be received in the operation hole 517. The latching pole 5136 is latched in the mounting hole 772, the unlocking member 70 is thus mounted to the shell 51. The position hole 75 of the unlocking member 70 aligns with the receiving portion 5135 of the installing hole 5132. Front ends of the rails 60 are inserted into the slide slots 515. The sliding plates 62 slidably abut against inner surfaces of the supporting plates 512. The guiding surfaces 67 of the abutting blocks 66 at the front ends of the rails 60 slidably abut against the supporting plate 512, deforming the tongues 65, until the abutting blocks 66 align with the second locating holes 516. The tongues 65 restore to bias the abutting blocks 66 to being latched in the second locating holes 516. Rear ends of the rails 60 are inserted into the installing space 26. The sliding plates 62 slidably abut against inner surfaces of the side plates 43. The guiding surfaces 67 of the abutting blocks 66 locating at the rear ends of the rails 60 slidably abut against the side plates 43, deforming the tongues 65, until the abutting blocks 66 align with the first locating holes 47. The tongues 65 restore to bias the abutting blocks 66 to being latched in the first locating holes 47. Thereby, the mounting apparatus 100 is mounted to the chassis 200, and the carrier 50 is exposed out of the bracket 40.

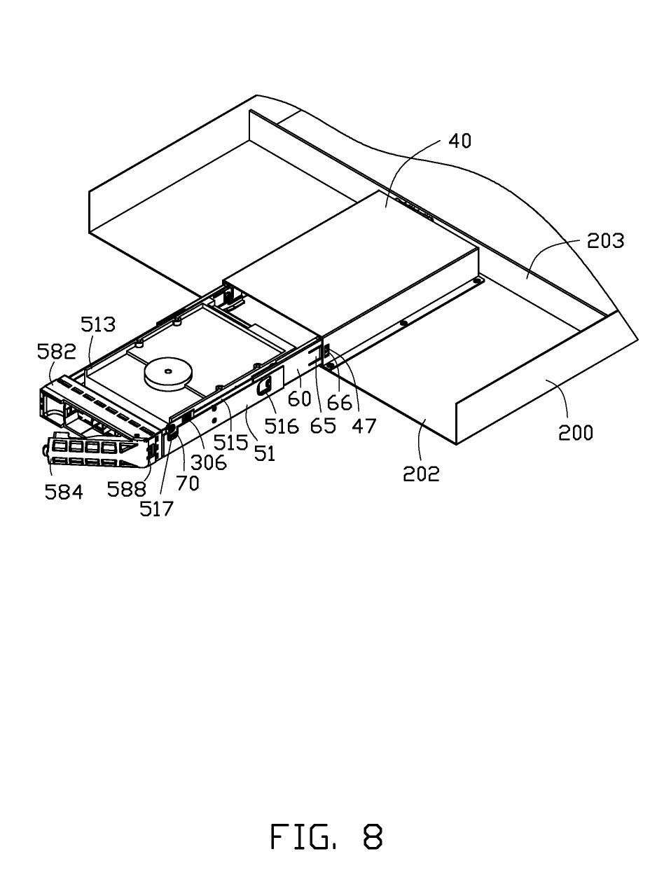

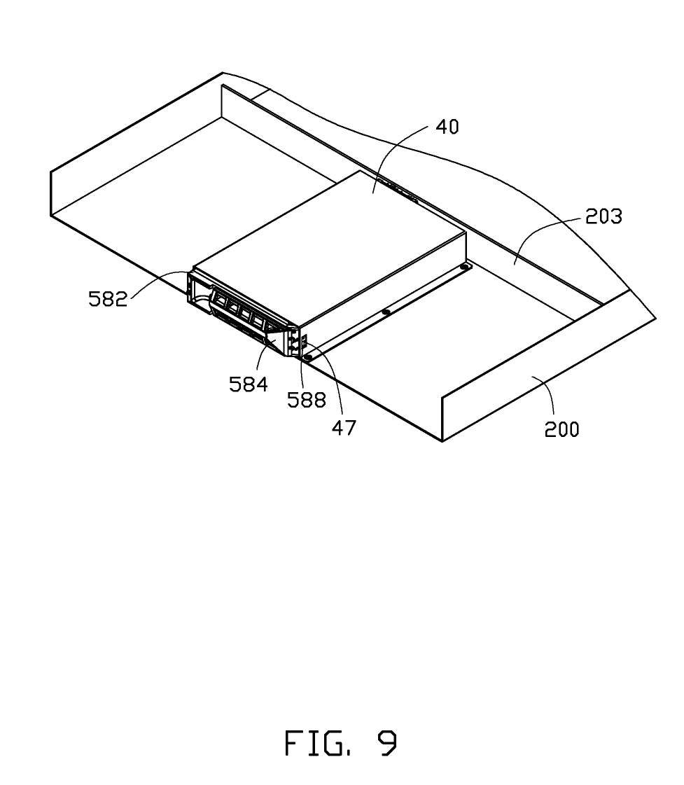

FIGS. 7-9 show that, in use, the HDD 300 is placed into the shell 51, with the pins 306 aligning with the installing holes 5132. The HDD 300 is moved down and then rearward. Each pin 306 is received in the receiving portion 5135 through the access portion 5133. Thus, the HDD 300 is supported on the base plate 511. In the above processes of assembling the HDD 300, one of the pins 306 slidably abuts against the abutting plate 72, deforming the abutting plate 72, until the pin 306 is latched in the position hole 75 of the unlocking member 70. The abutting plate 72 restores to abut against the pin 306. The latching member 584 is rotated away from the receiving space 585, until the block 588 is received in the connecting rack 582. The carrier 50 is pushed rearward toward the installing space 26, the guiding surfaces 67 of the abutting blocks 66 at the front ends of the rails 60 slidably abut against inner walls bounding the second locating holes 516, thus deforming the tongues 65. The abutting blocks 66 are detached from the second locating holes 516. The rails 60 are slidably received in the slide slots 515, until they are blocked by the poles 518. The guiding surfaces 67 of the abutting blocks 66 at the rear ends of the rails 60 slidably abut against inner walls bounding the first locating holes 47, deforming the tongues 65, until the abutting blocks 66 are detached from the first locating holes 47. A combination of the rails 60 and the carrier 50 is received in the installing space 26, and the second connector 304 of the HDD 300 is electrically coupled to the first connector 205 of the circuit board 203. The latching member 584 is rotated toward the receiving space 585. The block 588 is latched into the first locating hole 47, and the hook 587 is latched in the latching hole 586 of the connecting rack 582.

To detach the HDD 300 from the mounting apparatus 100, the hook 587 is deformed, until the hook 587 is detached from the latching hole 586. The latching member 584 is rotated away from the receiving space 585, until the block 588 is detached from the first locating hole 47. The carrier 50 is pulled out from the installing space 26. The second connector 304 is detached from the first connector 205. Thus, the carrier 50 can be moved out and exposed from of the bracket 42. The operation plate 74 is pressed through the operation hole 517, deforming the abutting plate 72, until the abutting plate 72 is detached from the pin 306. Thereby, the HDD 300 can be moved upward and detached from the carrier 50.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A carrier for mounting a hard disk drive having two opposite sidewalls and a pin extending out from one of the sidewalls, the carrier comprising:
a shell for receiving the hard disk drive, and comprising a supporting plate and a position plate extending in from a top of the supporting plate, wherein the supporting plate and the position plate cooperatively bound a slide slot, the position plate defines an installing hole for receiving the pin, the supporting plate defines an operation hole adjacent to the installing hole; and
an unlocking member installed in the slide slot, and comprising a resilient abutting plate and an operation plate extending from the abutting plate toward the operation hole, wherein the abutting plate defines a position hole aligning with the installing hole;
wherein, when mounting the hard disk, the pin of the hard disk drive is inserted in the installing hole, the pin slidably abuts against the abutting plate, deforming the abutting plate, until the pin is received in the position hole, the abutting plate is restored to abut against the pin, when detaching the hard disk drive, the operation plate is pressed through the operation hole, deforming the abutting plate, until the abutting plate is detached from the pin.

2. The carrier of claim 1, wherein the shell further comprises a base plate, the supporting plate extending up from a side of the base plate, the position plate is L-shaped, and the position plate extends in and then down from the top of the supporting plate.

3. The carrier of claim 2, wherein a latching pole protrudes from the position plate toward the operation hole, a resilient tongue extends from the unlocking member and adjacent to the operation plate, a distal end of the tongue defines a mounting hole, the latching pole is latched in the mounting hole of the tongue.

4. The carrier of claim 2, wherein the installing hole comprises an access portion extending down from a top of the position plate and a receiving portion extending rearward from a bottom end of the access portion, the position hole of the unlocking member aligns with the receiving portion.

5. A mounting apparatus for a hard disk drive having two opposite sidewalls and a pin extending out from one of the sidewalls, the mounting apparatus comprising:
a bracket; and
a carrier detachably received in the bracket, and comprising:
a shell for receiving the hard disk drive;
a resilient unlocking member installed on a side of the shell; and
an operation member comprising a connecting portion mounted to a front end of the shell and a latching member rotatably connected to the connecting portion;
wherein the unlocking member defines a position hole for receiving the pin of the hard disk drive, a front end of the bracket defines a first locating hole, a block protrudes out from a first end of the latching member to latch in the first locating hole, and a second end of the latching member is detachably latched to the connecting portion.

6. The mounting apparatus of claim 5, wherein the bracket comprises a top plate, two opposite side plates extending down from two sides of the top plate, the top plate and the side plates cooperatively bound an installing space for receiving the carrier, the first locating hole is defined in a front end of one of the side plates.

7. The mounting apparatus of claim 5, wherein the shell comprises a rectangular base plate, two supporting plates extending up from two opposite sides of the base plate, and two position plates extending in from top sides of the supporting plates, the supporting plates and the corresponding position plates cooperatively bound two parallel slide slots, the unlocking member is installed in one of the slide slots, the position plate defines an installing hole for receiving the pin of the hard disk drive, the unlocking member is located adjacent to the installing hole, the position hole of the unlocking member aligns with the installing hole of the position plate.

8. The mounting apparatus of claim 7, wherein the installing hole comprises an access portion extending down from a top of the position plate and a receiving portion extending rearward from a bottom end of the access portion, the position hole of the unlocking member aligns with the receiving portion, the pin of the hard disk drive is inserted in the installing hole, the pin slidably abuts against the abutting plate, deforming the abutting plate, until the pin is received in the position hole, the abutting plate is restored to abut against the pin.

9. The mounting apparatus of claim 7, wherein the carrier further comprises two rails slidably connected between the carrier and the bracket, each rail comprises a sliding plate received in the corresponding slide slots.

10. The mounting apparatus of claim 7, wherein rear ends of the supporting plates define two second locating holes, two resilient first tongues extend from the sliding plate, two abutting blocks extend out from distal ends of the first tongues, the abutting blocks are detachably latched into the first and second locating holes.

11. The mounting apparatus of claim 10, wherein each abutting block defines a slanting guiding surface opposite to a middle of the sliding plate.

12. The mounting apparatus of claim 10, wherein the supporting plate defines an operation hole adjacent to the unlocking member, the unlocking member comprises a resilient abutting plate and an operation plate slantingly extending from a front end of the abutting plate toward the operation hole, the position hole is defined in the abutting plate, the operation plate is pressed through the operation hole, deforming the abutting plate, until the abutting plate is detached from the pin.

13. The mounting apparatus of claim 12, wherein a latching pole protrudes from the position plate toward the operation hole, a resilient second tongue extends from the unlocking member and adjacent to the operation plate, a distal end of the tongue defines a mounting hole, the latching pole is latched in the mounting hole of the tongue.

14. An electronic device, comprising:
a hard disk drive comprising a side wall and a pin extending out from the side wall; and
a mounting apparatus comprising:
a bracket; and
a carrier received in the bracket and comprising:
a shell receiving the hard disk drive;
a resilient unlocking member installed on a side of the shell; and
an operation member comprising a connecting portion mounted to a front end of the shell and a latching member rotatably connected to the connecting portion;
wherein the unlocking member defines a position hole receiving the pin of the hard disk drive, a front end of the bracket defines a first locating hole, a block protrudes out from a first end of the latching member to latch in the first locating hole, and a second end of the latching member is detachably latched to the connecting portion.

15. The electronic device of claim 14, wherein the bracket comprises a top plate, two opposite side plates extending down from two sides of the top plate, the top plate and the side plates cooperatively bound an installing space for receiving the carrier, the first locating hole is defined in a front end of one of the side plates.

16. The electronic device of claim 14, wherein the shell comprises a rectangular base plate, two supporting plates extending up from two opposite sides of the base plate, and two position plates extending in from top sides of the supporting plates, the supporting plates and the corresponding position plates cooperatively bound two parallel slide slots, the unlocking member is installed in one of the slide slots, the position plate defines an installing hole for receiving the pin of the hard disk drive, the unlocking member is located adjacent to the installing hole, the position hole of the unlocking member aligns with the installing hole of the position plate.

17. The electronic device of claim 16, wherein the installing hole comprises an access portion extending down from a top of the position plate and a receiving portion extending forward from a bottom end of the access portion, the position hole of the unlocking member aligns with the receiving portion, the pin of the hard disk drive is inserted in the installing hole, the pin slidably abuts against the abutting plate, deforming the abutting plate, until the pin is received in the position hole, the abutting plate is restored to abut against the pin.

18. The electronic device of claim 16, wherein the carrier further comprises two rails slidably connected between the carrier and the bracket, each rail comprises a sliding plate received in the corresponding slide slots.

19. The electronic device of claim 18, wherein rear ends of the supporting plates define two second locating holes, two resilient first tongues extend from the sliding plate, two abutting blocks extend out from distal ends of the first tongues, the abutting blocks are detachably latched into the first and second locating holes.

20. The electronic device of claim 16, wherein the supporting plate defines an operation hole adjacent to the unlocking member, the unlocking member comprises a resilient abutting plate and an operation plate slantingly extending from an end of the abutting plate toward the operation hole, the operation plate is pressed through the operation hole, deforming the abutting plate, until the abutting plate is detached from the pin.
